(19) United States
(12) Patent Application Publication
(10) Pub. No.: US 2016/0150679 A1
(43) Pub. Date: May 26, 2016

(54) ELECTRONIC DEVICE

(71) Applicants: Inventec (Pudong) Technology Corporation, Shanghai (CN); INVENTEC CORPORATION, Taipei City (TW)

(72) Inventors: Yi-Lun CHENG, TAIPEI CITY (TW); Chih-Kai YANG, TAIPEI CITY (TW); Meng-Lung CHIANG, TAIPEI CITY (TW)

(21) Appl. No.: 14/675,721

(22) Filed: Mar. 31, 2015

(30) Foreign Application Priority Data
Nov. 26, 2014 (CN) 201410696049.5

(51) Int. Cl. H05K 7/20; H05K 5/03

(52) U.S. Cl. CPC H05K 7/20436; H05K 5/03; H05K 7/205

(57) ABSTRACT

An electronic device includes a housing, a heat generating element and a heat prevention module. The housing includes a case portion. The heat generating element is disposed inside the housing. The heat prevention module obstructs between the case portion and the heat generating element. The heat prevention module includes a first thermally conductive plate, a second thermally conductive plate and a third thermally conductive plate. The second thermally conductive plate obstructs between the first thermally conductive plate and the case portion. The third thermally conductive plate connects an edge of the first thermally conductive plate and an edge of the second thermally conductive plate.

### RELATED APPLICATIONS

This application claims priority to Chinese Application Serial Number 201410696049.5, filed Nov. 26, 2014, which is herein incorporated by reference.

### BACKGROUND

1. Technical Field

The present disclosure relates to electronic devices.

2. Description of Related Art

With the improvement of technology and the development of the Internet, the demand of people on electronic devices is getting higher. Moreover, the length of time that people daily spend on the electronic devices becomes longer. Meanwhile, notebook computer is one of those electronic devices which people uses for a long period of time everyday.

When a notebook computer is operating, some of the electronic elements become heat sources and release a relatively high energy of heat. Although notebook computers are in general designed with a cooling system to lower the temperature inside the notebook computers, the electronic elements as a heat source constantly radiate the heat to the surface of the housing of the notebook computers. In some circumstances, where the housing surface being heated up may only be concentrated in a small region.

In tradition, the industry usually adopts the highly conductive graphite sheet or metal sheet such as copper foil or aluminum foil, in order to rapidly conduct the heat located at the small region to the surroundings and lower the high temperature from the heat source. However, since the path of thermal conduction is from the heat source to the center of the graphite sheet or metal sheet facing the heat source, the temperature of the center of the graphite sheet or metal sheet is still high in view of the surroundings. If the user touches this small heated-up region for a certain period of time, he or she may feel uncomfortable or even get burned.

### SUMMARY

A technical aspect of the present disclosure provides an electronic device, which can effectively lower the temperature of the housing corresponding to the heat generating element.

According to an embodiment of the present disclosure, an electronic device includes a housing, a heat generating element and a heat prevention module. The housing includes a case portion. The heat generating element is disposed inside the housing. The heat prevention module obstructs between the case portion and the heat generating element. The heat prevention module includes a first thermally conductive plate, a second thermally conductive plate and a third thermally conductive plate. The second thermally conductive obstructs between the first thermally conductive plate and the case portion. The third thermally conductive plate connects an edge of the first thermally conductive plate and an edge of the second thermally conductive plate.

In one or more embodiments of the present disclosure, the first thermally conductive plate and the heat generating element are separated by a distance.

In one or more embodiments of the present disclosure, the first thermally conductive plate has a first reflective surface. The first reflective surface is located on a side of the first thermally conductive plate facing the heat generating element.

In one or more embodiments of the present disclosure, the first thermally conductive plate abuts the heat generating element, and the second thermally conductive plate and the case portion are separated by a distance.

In one or more embodiments of the present disclosure, the heat resistance module further includes a plurality of protruding structures. The protruding structures are disposed on a side of the second thermally conductive plate facing the case portion.

In one or more embodiments of the present disclosure, the first thermally conductive plate, the second thermally conductive plate and the third thermally conductive plate define a chamber, and the chamber is vacuum.

In one or more embodiments of the present disclosure, a coefficient of thermal conductivity of the first thermally conductive plate is larger than a coefficient of thermal conductivity of at least one of the second thermally conductive plate and the third thermally conductive plate.

In one or more embodiments of the present disclosure, the first thermally conductive plate, the second thermally conductive plate and the third thermally conductive plate define a chamber. The heat prevention module further includes at least one internal baffle. The internal baffle is arranged in sequence in the chamber between the first thermally conductive plate and the second thermally conductive plate.

In one or more embodiments of the present disclosure, the internal baffle has a second reflective surface. The second reflective surface is disposed on a side of the internal baffle facing the heat generating element.

In one or more embodiments of the present disclosure, the electronic device further includes a heatsink abutting a side of the heat generating element facing the heat resistance module. A surface area of the heatsink facing the heat resistance module is larger than a contact surface area of the heat generating element abutting the heatsink.

When compared with the prior art, the embodiments of the present disclosure mentioned above have at least the following advantages:

(1) Since the first thermally conductive plate has a high coefficient of thermal conductivity, when the first thermally conductive plate and the heat generating element are separated by a distance, the first thermally conductive plate can rapidly spread the heat being radiated to the surface of the first thermally conductive plate. Therefore, the formation of a hot spot because of the concentration of heat at a localized region is avoided, and thus the effect of heat resistance of the heat prevention module is enhanced. Furthermore, while maintaining the comfort of usage, the heat can be evenly distributed to the housing, and then transferred to the surroundings.
(2) When the first thermally conductive plate and the heat generating element are separated by a distance, the first reflective surface located on a side of the first thermally conductive plate facing the heat generating element, can lead to the reflection of a high ratio of heat but not transfer of heat to the first thermally conductive plate. Thus, the effect of heat resistance of the heat prevention module is enhanced.
(3) When the heat generated by the heat generating element is relatively high, the first thermally conductive plate abuts the heat generating element, and the second thermally conductive plate and the case portion are separated by a distance. Therefore, the heat generated by the heat generating element can be directly transmitted to the first thermally conductive plate by thermal conduction, and thus the efficiency of thermal conduction between the heat generating element and the first thermally conductive plate is increased.
(4) Since the heat is transmitted from the edge of the second thermally conductive plate to the center of the second thermally conductive plate, the temperature of the center of the second thermally conductive plate is lower than the edge of the second thermally conductive plate. Thus, the temperature of the case portion especially corresponding to the center location of the second thermally conductive plate can be effectively reduced.

### BRIEF DESCRIPTION OF THE DRAWINGS

The disclosure can be more fully understood by reading the following detailed description of the embodiments, with reference made to the accompanying drawings as follows:

FIG. 1 is a sectional view of an electronic device according to an embodiment of the present disclosure:

FIG. 2 is a sectional view of an electronic device according to another embodiment of the present disclosure;

FIG. 3 is a sectional view of an electronic device according to a further embodiment of the present disclosure;

FIG. 4 is a sectional view of an electronic device according to a further embodiment of the present disclosure;

FIG. 5 is a sectional view of an electronic device according to another embodiment of the present disclosure;

FIG. 6 is a sectional view of an electronic device according to a further embodiment of the present disclosure;

FIG. 7 is a sectional view of an electronic device according to a further embodiment of the present disclosure;

FIG. 8 is a sectional view of an electronic device according to another embodiment of the present disclosure;

FIG. 9 is a sectional view of an electronic device according to a further embodiment of the present disclosure; and

FIG. 10 is a sectional view of an electronic device according to a further embodiment of the present disclosure.

### DETAILED DESCRIPTION

Drawings will be used below to disclose a plurality of embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

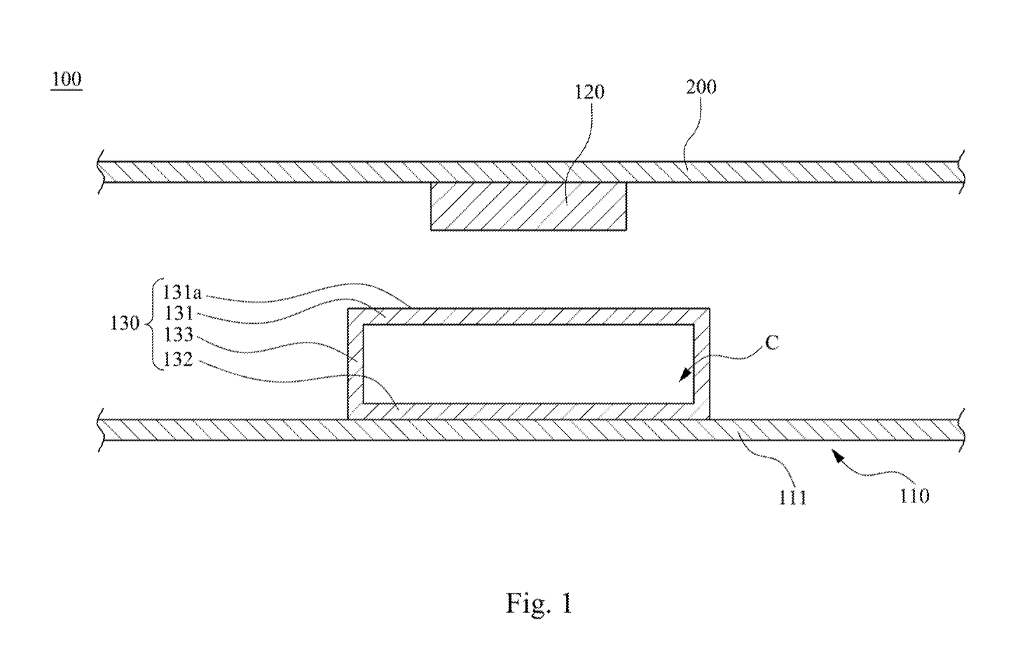

Please refer to FIG. 1. FIG. 1 is a sectional view of an electronic device 100 according to an embodiment of the present disclosure. As shown in FIG. 1, an electronic device 100 includes a housing 110, a heat generating element 120 and a heat prevention module 130. The housing 110 includes a case portion 111. The heat generating element 120 is disposed inside the housing 110. In this embodiment, the heat generating element 120 is connected to the circuit board 200 located inside the housing 110. The heat prevention module 130 obstructs between the case portion 111 and the heat generating element 120. The heat prevention module 130 includes a first thermally conductive plate 131, a second thermally conductive plate 132 and a third thermally conductive plate 133. The first thermally conductive plate 131 obstructs between the heat generating element 120 and the second thermally conductive plate 132. The second thermally conductive plate 132 obstructs between the first thermally conductive plate 131 and the case portion 111. The third thermally conductive plate 133 connects an edge of the first thermally conductive plate 131 and an edge of the second thermally conductive plate 132.

Furthermore, in this embodiment, the first thermally conductive plate 131 and the heat generating element 120 are separated by a distance, and the second thermally conductive plate 132 abuts the case portion 111. In other words, when the electronic device 100 operates and the heat generating element 120 generates heat, the heat generated by the heat generating element 120 and emitted towards the case portion 111 by thermal radiation is obstructed by the heat prevention module 130. Moreover, the heat is transmitted to the first thermally conductive plate 131 of the heat prevention module 130, such that the temperature of the first thermally conductive plate 131 increases. Consequently, the heat transmitted to the first thermally conductive plate 131, will be transmitted to the second thermally conductive plate 132 through the third thermally conductive plate 133 connected to the first thermally conductive plate 131, such that the temperature of the second thermally conductive plate 132 increases. After the thermal conduction of the heat prevention module 130 above, the temperature of the second thermally conductive plate 132 will be relatively lower than the temperature of the first thermally conductive plate 131. In addition, since the third thermally conductive plate 133 connects to the edge of the second thermally conductive plate 132, the heat is conducted to the center of the second thermally conductive plate 132 from the edge of the second thermally conductive plate 132. Therefore, the temperature of the center of the second thermally conductive plate 132 will be lower than the temperature of the edge of the second thermally conductive plate 132 in a further extent. The heat conducted to the case portion 111 from the center of the second thermally conductive plate 132, will thus be obviously less than the heat directly emitted from the heat generating element 120 by thermal radiation. In this way, the temperature of the case portion 111, especially corresponding to the center location of the second thermally conductive plate 132, can be effectively reduced.

In the practical applications, both the first thermally conductive plate 131 and the second thermally conductive plate 132 are materials of a high thermal conductivity, with the coefficient of thermal conductivity larger than 10 W/mK. For instance, the material of the first thermally conductive plate 131 and the second thermally conductive plate 132 can be graphite, graphene and metal such as copper or aluminum. However, this choice of materials of the first thermally conductive plate 131 and the second thermally conductive plate 132 does not intend to limit the present disclosure.

In order to decrease the heat transmitted to the first thermally conductive plate 131 from the heat generating element 120 by thermal radiation, the first thermally conductive plate 131 has a first reflective surface 131a. The first reflective surface 131a is located on a side of the first thermally conductive plate 131 facing the heat generating element 120, configured to reduce the coefficient of thermal conductivity of the first thermally conductive plate 131. To be more specific, when the heat emitted from the heat generating element 120 by thermal radiation reaches the first reflective surface 131a, a high ratio of heat will be reflected by the first reflective surface 131a but not transferred to the first thermally conductive plate 131. Thus, the effect of heat resistance of the heat prevention module 130 is enhanced.

In the practical applications, the first reflective surface 131a can be formed by affixing copper foil or aluminum foil on the first thermally conductive plate 131 facing the heat generating element 120, or by surface treatment methods such as electroplating or polishing. It is noted that the forming method of the first reflective surface 131a as cited herein is only illustrative and is not to limit the claimed scope. A person having ordinary skill in the art of the present disclosure should appropriately choose the forming method of the first reflective surface 1311a depending on actual needs.

On the other hand, the first thermally conductive plate 131, the second thermally conductive plate 132 and the third thermally conductive plate 133 define a chamber C. In the practical applications, there can be air inside the chamber C. Or, in order to reduce the thermal conductivity of the chamber C, the chamber C can be vacuum, such that heat cannot be transmitted from the first thermally conductive plate 131 to the second thermally conductive plate 132 by thermal convection and thermal conduction. Thus, the heat is forced to be transmitted from the first thermally conductive plate 131, through the third thermally conductive plate 133 and finally to the second thermally conductive plate 132 by thermal conduction as aforementioned. In an embodiment, the degree of vacuum of the chamber C is 0.05-0.1 Torr. However, this does not intend to limit the present disclosure. In another embodiment, the degree of vacuum of the chamber C is 0.01-0.1 Torr. However, again, this does not intend to limit the present disclosure.

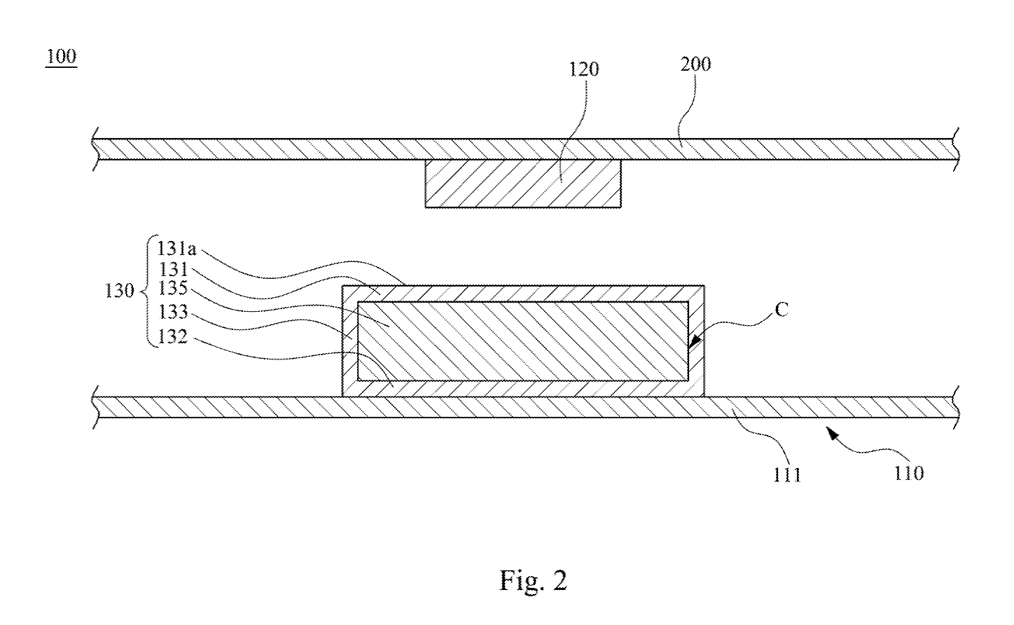

Please refer to FIG. 2. FIG. 2 is a sectional view of an electronic device 100 according to another embodiment of the present disclosure. As shown in FIG. 2, in order to further reduce the thermal conductivity of the chamber C, the heat prevention module 130 further includes a heat insulation material 135. The heat insulation material 135 is located inside the chamber C, configured to obstruct the transmission of heat from the first thermally conductive plate 131 to the second thermally conductive plate 132 through the chamber C. Thus, the heat is forced to be transmitted from the first thermally conductive plate 131, through the third thermally conductive plate 133 and finally to the second thermally conductive plate 132 by thermal conduction as aforementioned. In general, the heat insulation material 135 can be a material of low thermal conductivity such as a foam material. However, this does not intend to limit the present disclosure.

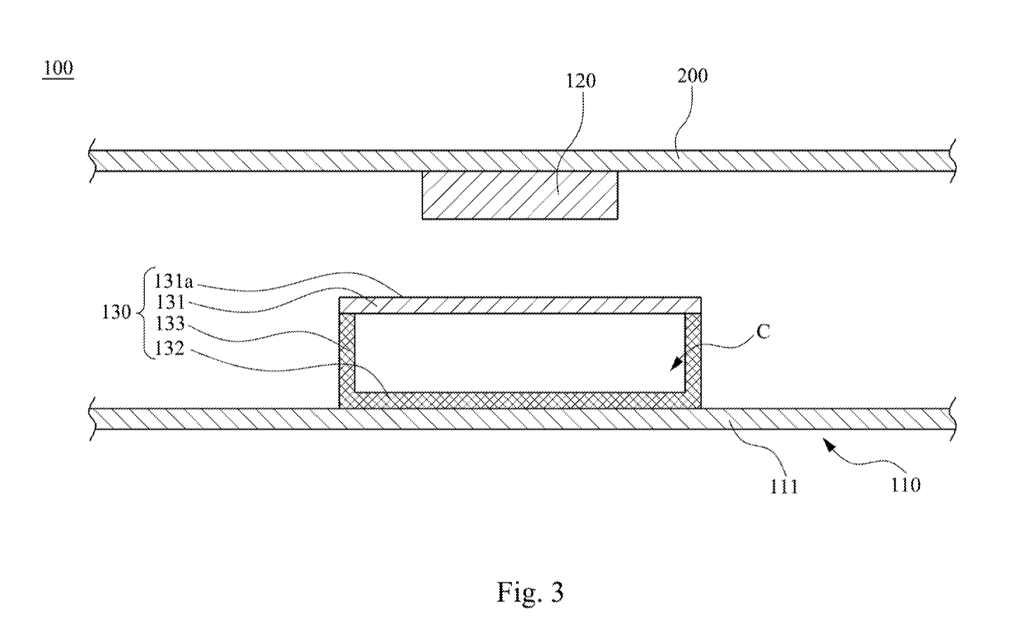

Please refer to FIG. 3. FIG. 3 is a sectional view of an electronic device 100 according to a further embodiment of the present disclosure. In the practical applications, the first thermally conductive plate 131, the second thermally conductive plate 132 and the third thermally conductive plate 133 can be materials of different thermal conductivities. To be more specific, the coefficient of thermal conductivity of the first thermally conductive plate 131 can be larger than the coefficient of thermal conductivity of at least one of the second thermally conductive plate 132 and the third thermally conductive plate 133. As shown in FIG. 3, in this embodiment, the thermally conductive material of the third thermally conductive plate 133 and the thermally conductive material of the second thermally conductive plate 132 are the same. The thermally conductive material of the first thermally conductive plate 131 can be material of a relatively higher coefficient of thermal conductivity, i.e., material with a better thermal conductivity. The thermally conductive material of the second thermally conductive plate 132 and the third thermally conductive plate 133 can be material of a relatively lower coefficient of thermal conductivity, i.e., material with a relatively worse thermal conductivity. During configuration, since the first thermally conductive plate 131 is closer to the heat generating element 120, and the second thermally conductive plate 132 is relatively farther away from the heat generating element 120, the thermally conductive plate 131 can rapidly transmit the heat throughout the thermally conductive plate 131 in an even manner. In contrast, the heat on the thermally conductive plate 131 is relatively uneasy to be transmitted to the case portion 111 of the housing 110 through the second thermally conductive plate 132 and the third thermally conductive plate 133, such that the effect of heat resistance of the heat prevention module 130 is enhanced.

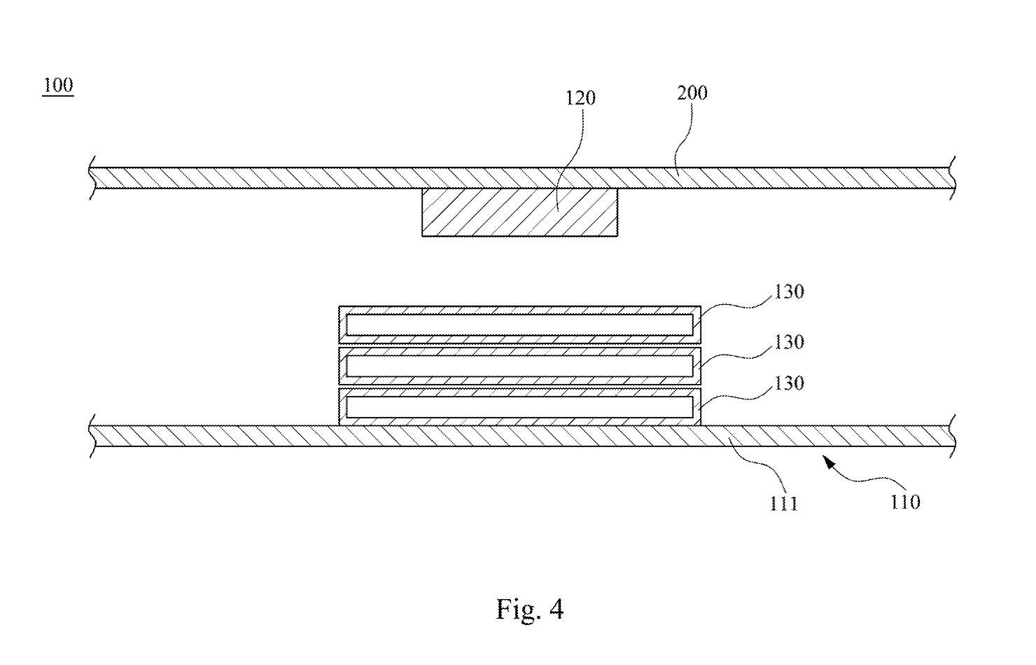

Please refer to FIG. 4. FIG. 4 is a sectional view of an electronic device 100 according to a further embodiment of the present disclosure. In the practical applications, the quantity of the heat prevention module 130 can be more than one. As shown in FIG. 4, the quantity of the heat prevention modules 130 is three, and the heat prevention modules 130 are disposed between the heat generating element 120 and the case portion 111 in a stacking manner. In this way, the path of conduction through the heat prevention modules 130 will become longer. Thus, the heat prevention modules 130 can together enhance the effect of heat resistance.

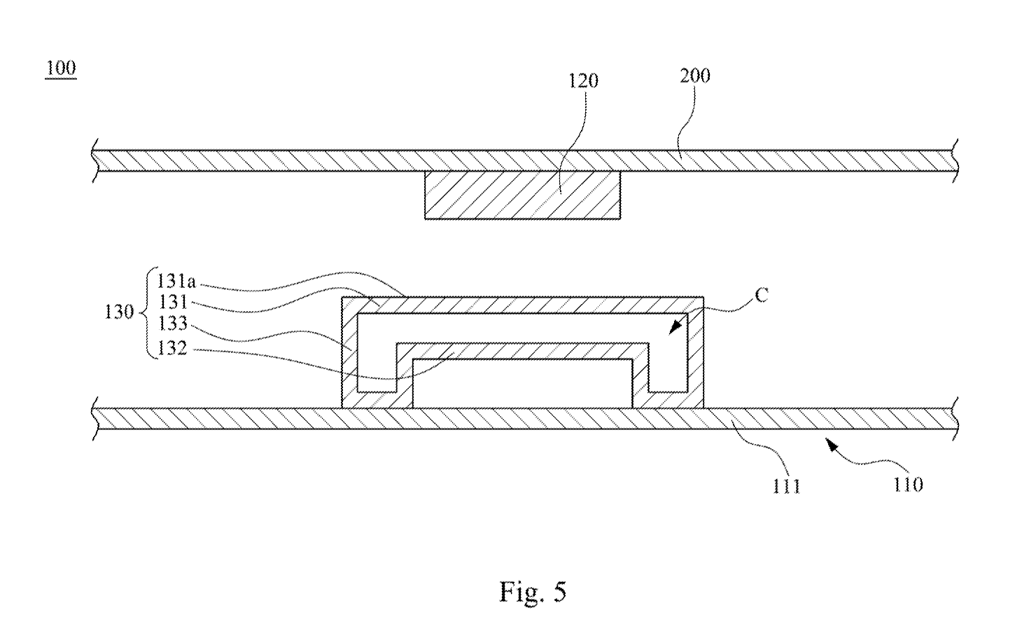

Please refer to FIG. 5. FIG. 5 is a sectional view of an electronic device 100 according to another embodiment of the present disclosure. As shown in FIG. 5, the second thermally conductive plate 132 and the case portion 111 are separated by a distance. In this way, the center part of the second thermally conductive plate 132 will not abut the case portion 111, and thus the heat located at the center part of the second thermally conductive plate 132 cannot be directly conducted to the case portion 111 by thermal conduction.

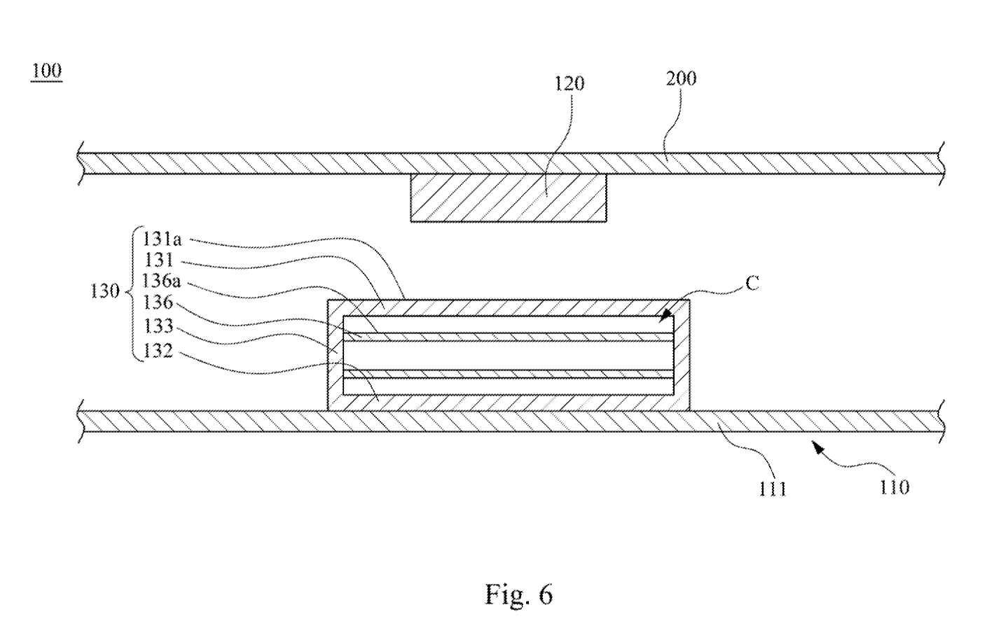

Please refer to FIG. 6. FIG. 6 is a sectional view of an electronic device 100 according to a further embodiment of the present disclosure. In this embodiment, the heat prevention module 130 further includes at least one internal baffle 136. As shown in FIG. 6, the quantity of the internal baffles 136 is two, and the internal baffles 136 are arranged in sequence in the chamber C between the first thermally conductive plate 131 and the second thermally conductive plate 132. Through the limitation of space, the arrangement of the internal baffles 136 can obstruct the transmission of heat from the first thermally conductive plate 131 to the second thermally conductive plate 132 by thermal convection. In addition, the internal baffles 136 can perform the function of reflection. When the heat is emitted from the first thermally conductive plate 131 to the second thermally conductive plate 132 by thermal radiation, the internal baffles 136 located between the first thermally conductive plate 131 and the second thermally conductive plate 132 can reflect the heat back to the first thermally conductive plate 131. Thus, the heat located in the first thermally conductive plate 131 is forced to reach the second thermally conductive plate 132 through the third thermally conductive plate 133.

In order to make the internal baffle 136 to reflect more heat, the internal baffle 136 has a second reflective surface 136a. The second reflective surface 136a is disposed on a side of the internal baffle 136 facing the heat generating element 120 (i.e., facing the first thermally conductive plate 131), configured to reduce the coefficient of thermal conductivity of the internal baffle 136. To be more specific, when the heat emitted from the first thermally conductive plate 131 by thermal radiation reaches the second reflective surface 136a, a high ratio of heat will be reflected by the second reflective surface 136a but not transferred to the internal baffle 136. Thus, the heat located in the first thermally conductive plate 131 is forced to reach the second thermally conductive plate 132 through the third thermally conductive plate 133, and the effect of heat resistance of the heat prevention module 130 is enhanced.

In the practical applications, the second reflective surface 136a can be formed by affixing copper foil or aluminum foil on the internal baffle 136 facing the heat generating element 120 (i.e., facing the first thermally conductive plate 131), or by surface treatment methods such as electroplating or polishing. It is noted that the forming method of the second reflective surface 136a as cited herein is only illustrative and is not to limit the claimed scope. A person having ordinary skill in the art of the present disclosure should appropriately choose the forming method of the second reflective surface 136a depending on actual needs.

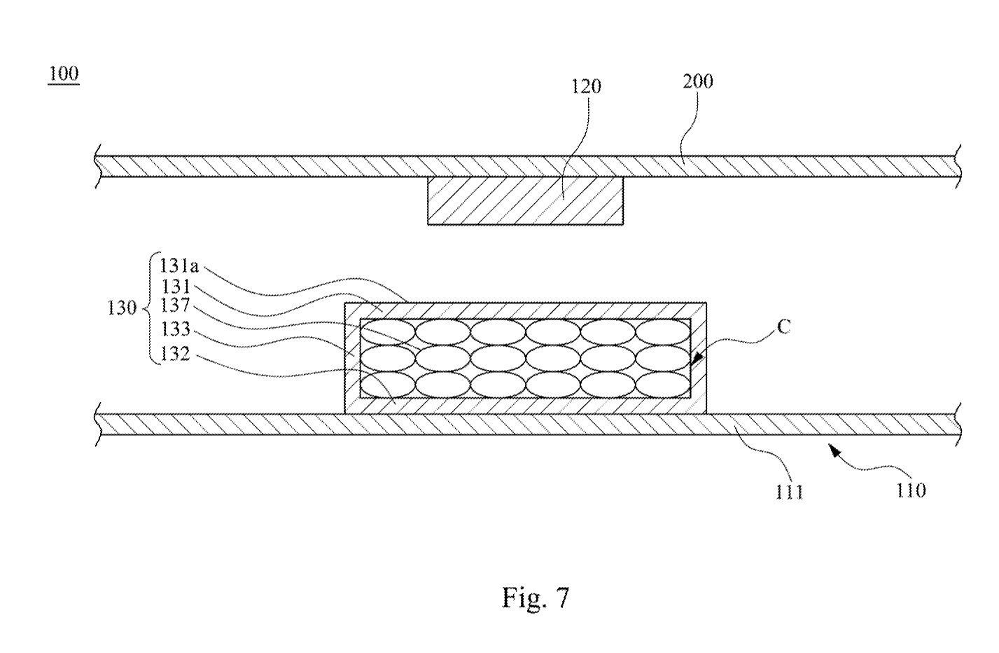

Please refer to FIG. 7. FIG. 7 is a sectional view of an electronic device 100 according to a further embodiment of the present disclosure. As shown in FIG. 7, the heat prevention module 130 further includes a plurality of hollow structures 137. The hollow structures 137 are distributed in the chamber C, configured to obstruct the transmission of heat from the first thermally conductive plate 131 to the second thermally conductive plate 132 by thermal convection.

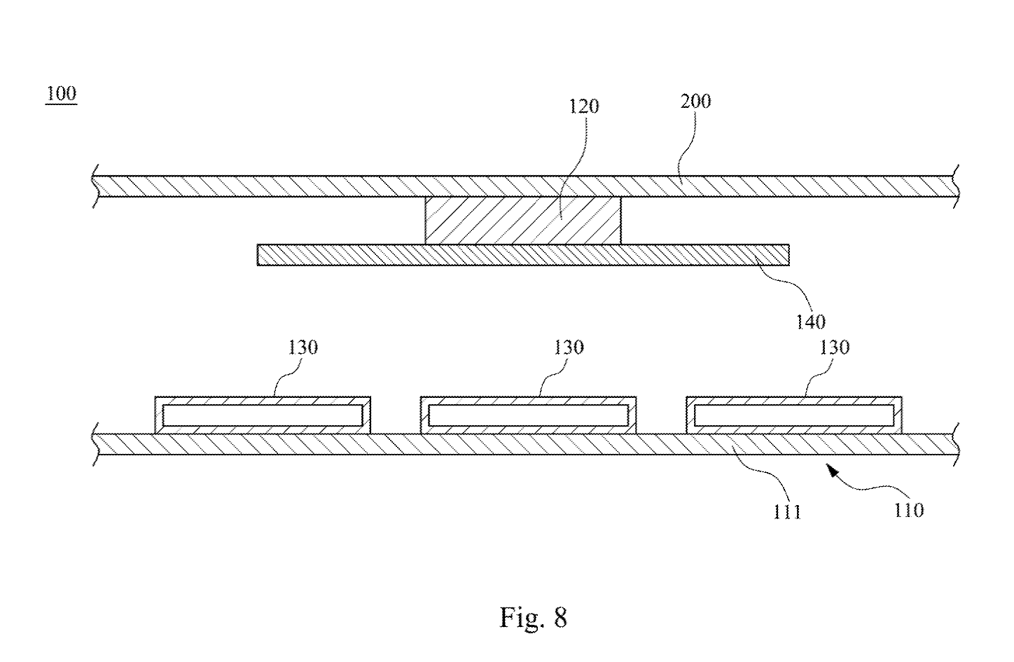

Please refer to FIG. 8. FIG. 8 is a sectional view of an electronic device 100 according to another embodiment of the present disclosure. As shown in FIG. 8, the electronic device 100 further includes a heatsink 140. The heatsink 140 abuts a side of the heat generating element 120 facing the heat resistance module 130. Technically speaking, the surface area of the heatsink 140 facing the heat resistance module 130 is larger than the contact surface area of the heat generating element 120 abutting the heatsink 140. In this way, the heat generated during the operation of the heat generating element 120 can be spread to the direction of the heat resistance module 130 through the heatsink 140, such that the over-concentration of the heat generated by the heat generating element 120 towards the heat resistance module 130 is avoided. With the configuration of the heatsink 140, in this embodiment, the quantity of the heat resistance module 130 can be more than one. As shown in FIG. 8, the quantity of the heat resistance module 130 is three, and the heat prevention modules 130 are disposed between the heatsink 140 and the case portion 111 in a parallel manner. The heat prevention modules 130 respectively abuts the case portion 111, so as to correspond to the heatsink 140 and obstruct the heat emitted from the heatsink 140 to the case portion 111 by thermal convection.

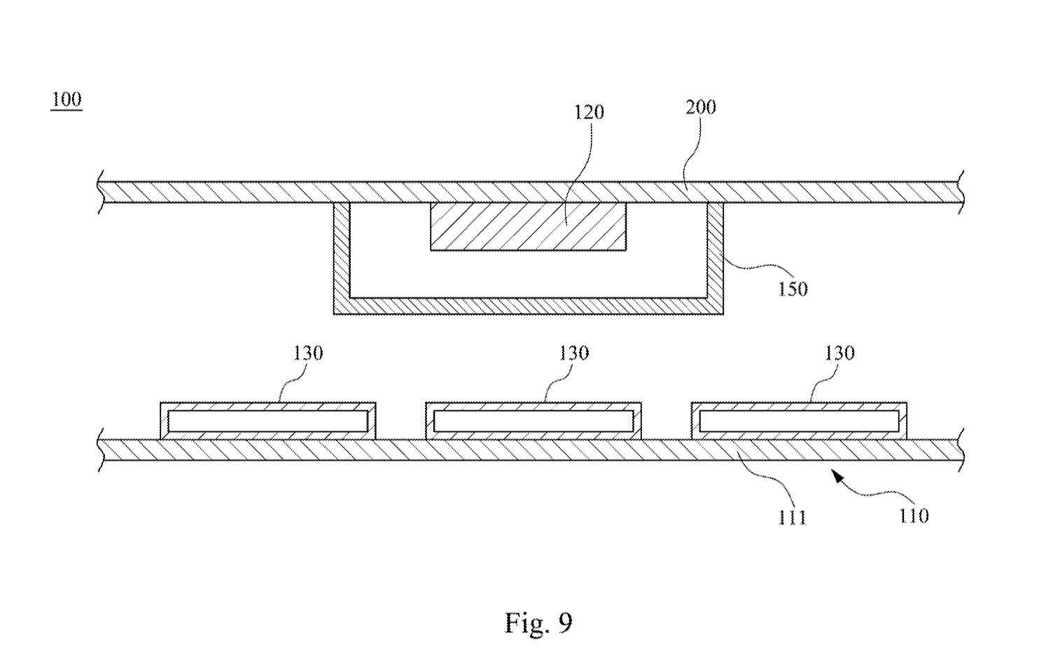

Please refer to FIG. 9. FIG. 9 is a sectional view of an electronic device 100 according to a further embodiment of the present disclosure. As shown in FIG. 9, in order to achieve the effect of shielding for electromagnetic interference, the electronic device 100 further includes a shielding structure for electromagnetic interference 150. The shielding structure for electromagnetic interference 150 is located between the heat generating element 120 and the heat resistance module 130. In this embodiment, the shielding structure for electromagnetic interference 150 is in a shape of a hood, covering the heat generating element 120.

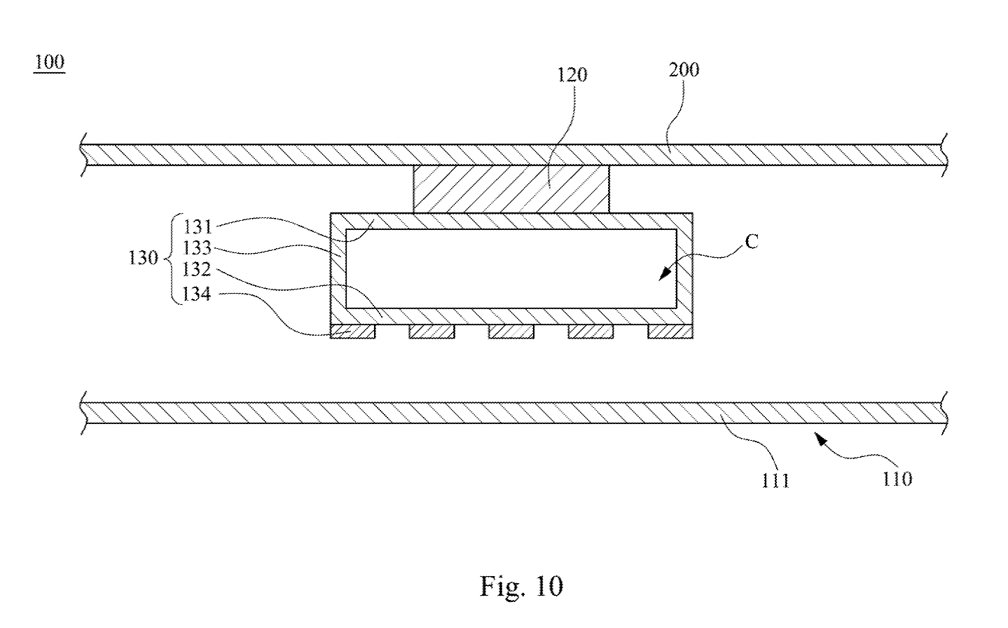

Please refer to FIG. 10, FIG. 10 is a sectional view of an electronic device 100 according to a further embodiment of the present disclosure. When the heat generated by the heat generating element 120 is relatively high, in order to achieve for a better effect of heat resistance, as shown in FIG. 10, the first thermally conductive plate 131 of the heat resistance module 130 can abut the heat generating element 120, and the second thermally conductive plate 132 and the case portion 111 are separated by a distance. In this way, the heat generated by the heat generating element 120 can be directly transmitted to the first thermally conductive plate 131 by thermal conduction, and the efficiency of thermal conduction between the heat generating element 120 and the first thermally conductive plate 131 is increased. Consequently, the heat is conducted to the second thermally conductive plate 132 through the third thermally conductive plate 133, and the heat in the second thermally conductive plate 132 will be emitted to the case portion 111 by thermal radiation.

In order to facilitate the heat transmission from the second thermally conductive plate 132 to the case portion 111 by thermal radiation, the heat resistance module 130 further includes a plurality of protruding structures 134. The protruding structures 134 are disposed on a side of the second thermally conductive plate 132 facing the case portion 111, in order to increase the surface area of the second thermally conductive plate 132 facing the case portion 111. In the practical applications, the protruding structures 134 can be bumps or fins. However, this does not intend to limit the present disclosure.

In summary, when compared with the prior art, the embodiments of the present disclosure mentioned above have at least the following advantages:

(1) Since the first thermally conductive plate has a high coefficient of thermal conductivity, when the first thermally conductive plate and the heat generating element are separated by a distance, the first thermally conductive plate can rapidly spread the heat being radiated to the surface of the first thermally conductive plate. Therefore, the formation of a hot spot because of the concentration of heat at a localized region is avoided, and thus the effect of heat resistance of the heat prevention module is enhanced. Furthermore, while maintaining the comfort of usage, the heat can be evenly distributed to the housing, and then transferred to the surroundings.
(2) When the first thermally conductive plate and the heat generating element are separated by a distance, the first reflective surface located on a side of the first thermally conductive plate facing the heat generating element, can lead to the reflection of a high ratio of heat but not transfer of heat to the first thermally conductive plate. Thus, the effect of heat resistance of the heat prevention module is enhanced.
(3) When the heat generated by the heat generating element is relatively high, the first thermally conductive plate abuts the heat generating element, and the second thermally conductive plate and the case portion are separated by a distance. Therefore, the heat generated by the heat generating element can be directly transmitted to the first thermally conductive plate by thermal conduction, and thus the efficiency of thermal conduction between the heat generating element and the first thermally conductive plate is increased.
(4) Since the heat is transmitted from the edge of the second thermally conductive plate to the center of the second thermally conductive plate, the temperature of the center of the second thermally conductive plate is lower than the edge of the second thermally conductive plate. Thus, the temperature of the case portion especially corresponding to the center location of the second thermally conductive plate can be effectively reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. An electronic device, comprising:
a housing comprising a case portion;
a heat generating element disposed inside the housing; and
a heat prevention module obstructing between the case portion and the heat generating element, the heat prevention module comprising:
a first thermally conductive plate;
a second thermally conductive plate obstructing between the first thermally conductive plate and the case portion; and
a third thermally conductive plate connecting an edge of the first thermally conductive plate and an edge of the second thermally conductive plate.

2. The electronic device of claim 1, wherein the first thermally conductive plate and the heat generating element are separated by a distance.

3. The electronic device of claim 2, wherein the first thermally conductive plate has a first reflective surface located on a side of the first thermally conductive plate facing the heat generating element.

4. The electronic device of claim 1, wherein the first thermally conductive plate abuts the heat generating element, and the second thermally conductive plate and the case portion are separated by a distance.

5. The electronic device of claim 4, wherein the heat resistance module further comprises a plurality of protruding structures disposed on a side of the second thermally conductive plate facing the case portion.

6. The electronic device of claim 1, wherein the first thermally conductive plate, the second thermally conductive plate and the third thermally conductive plate define a chamber, and the chamber is vacuum.

7. The electronic device of claim 1, wherein a coefficient of thermal conductivity of the first thermally conductive plate is larger than a coefficient of thermal conductivity of at least one of the second thermally conductive plate and the third thermally conductive plate.

8. The electronic device of claim 1, wherein the first thermally conductive plate, the second thermally conductive plate and the third thermally conductive plate define a chamber, and the heat prevention module further comprises at least one internal baffle arranged in sequence in the chamber between the first thermally conductive plate and the second thermally conductive plate.

9. The electronic device of claim 8, wherein the internal baffle has a second reflective surface disposed on a side of the internal baffle facing the heat generating element.

10. The electronic device of claim 1, further comprising a heatsink abutting a side of the heat generating element facing the heat resistance module, a surface area of the heatsink facing the heat resistance module being larger than a contact surface area of the heat generating element abutting the heatsink.
